(19) United States
(12) Patent Application Publication
(10) Pub. No.: US 2008/0271471 A1
(43) Pub. Date: Nov. 6, 2008

(54) Temperature Controlling Method for Substrate Processing System and Substrate Processing System

(76) Inventors: Toshihisa Nozawa, Hyogo-Ken (JP); Koji Kotani, Hyogo-Ken (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 10/583,847

(22) PCT Filed: Dec. 24, 2004
(86) PCT No.: PCT/JP2004/019406

§ 371 Date: Jul. 15, 2008

(30) Foreign Application Priority Data
Dec. 25, 2003 (JP) 2003-430954
Nov. 29, 2004 (JP) 2004-344150

(51) Int. Cl. G05D 23/19; F25D 17/02; H01L 21/205

(52) U.S. Cl. 62/179; 62/259.2; 62/173; 118/724

(57) ABSTRACT

A substrate processing system comprises a plurality of CVD processing units (15a-15c) and one refrigerator (101). A supply line (102) for supplying a cooling medium from the refrigerator to the CVD processing units, and a feedback line (103) for feeding the cooling medium back to the refrigerator from the processing units are laid in the system. The cooling medium from the refrigerator is thus distributively fed to the processing units. Circuits (104a-104c) are laid out in rod stages (33), objects of temperature control, in the respective processing units. Each circuit is connected to the supply line and to the feedback line. The cooling medium is circulated around the circuits to control the temperatures of the rod stages stably. When the temperature of the rod stage rises, the cooling medium at a low temperature is taken in the circuit from the supply line to cool the rod stage.

### BACKGROUND OF THE INVENTION

1. Field of the Invention

The present invention relates to a method of controlling the temperatures of two or more substrate processing units that constitute a substrate processing system, and to a substrate processing system comprising a plurality of substrate processing units whose temperatures are controllable.

2. Background Art

In a process for manufacturing a semiconductor device or the like, there is conducted plasma processing in which a wafer is processed with plasma, such as film deposition processing or etching processing.

Such plasma processing is usually conducted in two or more wafer processing units installed in a factory. The plasma processing is conducted in processing vessels in the wafer processing units under high-temperature conditions, and, in order to keep the wafer processing conditions constant, it is necessary to hold the inside of each processing vessel at a constant temperature during processing. Therefore, each wafer processing unit installed in a factory has been provided with a chiller that removes the heat reserved in the processing vessel, etc. so that the wafer processing unit does not reach an excessively high temperature. This chiller can keep the temperature of the processing vessel constant by feeding a cooling medium to the wafer processing unit and letting the cooling medium absorb the heat of the processing vessel, for example.

However, the above-described chiller has usually been installed in a place far from the wafer processing unit, e.g., under the floor (see Japanese Laid-Open Patent Publication No. 2001-332463, for example). Therefore, a long pipe that links the chiller with the wafer processing unit has been required for each wafer processing unit. Further, flon with a specific gravity of about 2, for example, has usually been used as the cooling medium for the above chiller, and a relatively big pipe has been needed to suppress piping resistance. It is therefore necessary to lay, in a factory, a big and long pipe for each pair of chiller and wafer processing unit, so that a large space has been needed to lay the pipes. Furthermore, the cost for laying the pipes has been high. Moreover, a powerful pump is needed to feed the cooling medium from the chiller to the wafer processing unit on the floor through the big, long pipe, and such a pump has been a cause of excessively heavy loading on the chiller and the pump. For this reason, the energy loss of the chiller and the pump during operation has been great, and the energy cost, such as power consumption, has been increasing.

### SUMMARY OF THE INVENTION

In view of the aforementioned drawbacks in the prior art, the present invention was accomplished. In a substrate processing system comprising a plurality of substrate processing units such as wafer processing units, an object of the invention is to save piping space and to realize temperature control with decreased energy at lower cost.

According to an aspect of the present invention, there is provided to fulfill this object a temperature controlling method for a substrate processing system comprising a plurality of substrate processing units each having objects of temperature control, characterized in that the temperatures of the objects of temperature control in the substrate processing units are controlled by distributively feeding a cooling medium to the substrate processing units from one refrigerator (refrigerating machine).

According to this temperature controlling method, a cooling medium is distributively fed to a plurality of the substrate processing units from one refrigerator, so that this method can make the number of pipes to be laid in the substrate processing system smaller as compared with the prior art and can thus save piping space. Further, one refrigerator is enough for this temperature controlling method although a plurality of chillers have been installed in the prior art as mentioned above, so that this method can save installation space. Furthermore, this temperature controlling method needs less electric power as compared with a conventional method using a plurality of chillers and pumps and can thus achieve reduction in energy and cost.

In each substrate processing unit, it is preferable to circulate the cooling medium, supplied by the refrigerator, around a circuit laid out in the object of temperature control. By doing so, the temperatures of the objects of temperature control in the substrate processing units can be separately regulated properly. Further, since the heat exchange rate in each substrate processing unit is optimized, the cooling medium in the circuit can remain uniform in temperature, and the temperature of the object of temperature control can be uniformly controlled.

In this case, it is preferable to control separately the temperatures of the objects of temperature control also by separately regulating the flow velocity of the cooling medium in the circuits in the substrate processing units. For example, the cooling medium circulating around each circuit can remain more uniform in temperature when the flow rate of the cooling medium in the circuit is increased. Consequently, the temperatures of the objects of temperature control can be controlled more uniformly.

Depending on the temperatures of the objects of temperature control, it is preferable to do the following operation (a) or (b) selectively:
(a) suspending supply of the cooling medium from the refrigerator to the circuits in the substrate processing units, and continuing to control the temperatures of the objects of temperature control substantially only by the cooling medium circulating around the circuits; or
(b) controlling the temperatures of the objects of temperature control by circulating the cooling medium around the circuits, while supplying the cooling medium from the refrigerator to the circuits in the substrate processing units.

In the case where the temperatures of the objects are controlled in the above-described manner (a), temperature control is done by the cooling medium in the circuits, which is uniform in temperature, so that stable temperature control can be achieved. Further, since there is no need to supply the cooling medium freshly, this manner can economize cooling medium supply energy, for example.

On the other hand, when the temperatures of the objects are controlled in the above-described manner (b), it is possible to change the temperature of the cooling medium circulating around the circuits by feeding the cooling medium to the circuits from the refrigerator. For example, if the objects of temperature control reach temperatures not in predetermined temperature ranges, the temperatures of the objects can be regulated so that they fall in the predetermined temperature ranges.

Also in this case, it is preferable to control separately the temperatures of the objects of temperature control by separately regulating the flow rates of the cooling medium in the circuits in the substrate processing units.

According to another aspect of the present invention, there is provided a substrate processing system comprising:

a plurality of substrate processing units having objects of temperature control,

a refrigerator,

a supply line for supplying a cooling medium from the refrigerator to the substrate processing units,

a feedback line for feeding the cooling medium back to the refrigerator from the substrate processing units,

circuits, each connected to the supply line and to the feedback line, which allow the cooling medium to circulate through the objects of temperature control in the substrate processing units, and

regulating valves for regulating separately the flow rates of the cooling medium flowing into the circuits from the supply line.

According to this substrate processing system, it is possible to feed a cooling medium distributively to a plurality of the substrate processing units from one refrigerator. Therefore, this substrate processing system requires only a smaller number of pipes as compared with a conventional system and can thus save piping space. Further, since this processing system does not require a chiller for each one of the substrate processing units like a conventional system, it can save installation space. Furthermore, the substrate processing system of the invention consumes less electric power as compared with a conventional system comprising a plurality of chillers and pumps, so that it can achieve reduction in energy and cost. In addition, the temperatures of the objects of temperature control can be controlled by allowing the cooling medium supplied by the refrigerator to the substrate processing units to circulate around the circuits. In this case, the temperatures of the objects of temperature control can be regulated properly with the cooling medium circulating around the circuits. Moreover, since the cycle of circulation of the cooling medium around each circuit is relatively short, the cooling medium in the circuit can remain uniform in temperature and the temperature of the object of temperature control can thus be uniformly controlled.

The regulating valves may be three-way valves that can switch states from

one in which the cooling medium circulates substantially only around the circuits, to

the other in which the cooling medium circulates between the refrigerator and the substrate processing units through the supply line, the circuits, and the feedback line,

or from the latter state to the former.

Preferably, the substrate processing system of the present invention further comprises

temperature sensors for sensing the temperatures of the objects of temperature control, and

valve controllers for controlling the regulating valves according to the temperatures sensed by the temperature sensors.

In the system having the above two, if the temperature sensor shows that the temperature of the object of temperature control is not in a predetermined temperature range, the valve controller opens the valve to supply the cooling medium to the circuit from the refrigerator. By this, the temperature of the cooling medium in the circuit is changed, and the temperature of the object of temperature control can therefore be controlled so that it falls in a predetermined temperature range.

The substrate processing system comprising the temperature sensors and the valve controllers may further comprise

heaters for heating the cooling medium circulating around the circuits, and

heat controllers for controlling the heaters according to the temperatures sensed by the temperature sensors.

In the substrate processing system further comprising the above two, if the temperature of the object of temperature control becomes lower than the target temperature, it can be raised to the target temperature by heating the cooling medium with the heater that is under the control of the heat controller.

The circuits may be provided with pumps useful to circulate the cooling medium.

The pump can facilitate circulation of the cooling medium around the circuit and can thus increase the flow velocity of the cooling medium in the circuit. Consequently, the cooling medium in the circuit can remain more uniform in temperature, and the temperature of the object of temperature control can be controlled more uniformly.

In this case, it is preferable to provide the circuits with buffer tanks for the cooling medium. The buffer tanks suppress changes in pressure in the circuits that occur during operation of the pumps and can thus ensure the stable flow of the cooling medium.

Preferably, the substrate processing system of the present invention further comprises

a by-pass line that by-passes the substrate processing units and links the supply line with the feedback line, and

an on-off valve for opening or closing the by-pass line.

The above-described substrate processing units are useful to process substrates with plasma produced in them, for example. Such substrate processing units generate a large amount of heat, and, moreover, demand strict temperature control. For this reason, application of the present invention to the substrate processing units is particularly effective.

### BRIEF DESCRIPTION OF THE DRAWINGS

FIG. 1 is a plane view schematically showing the structure of a substrate processing system 1.

FIG. 2 is a longitudinal sectional view schematically showing the structure of a CVD processing unit.

FIG. 3 is a diagrammatic view schematically showing the structure of a temperature controller.

FIG. 4 is a diagrammatic view schematically showing the structure of a temperature controller having a heater.

FIG. 5 is a longitudinal sectional view schematically showing the structure of a CVD processing unit in the case where the temperature of the ceiling and sidewall of a frame is controlled.

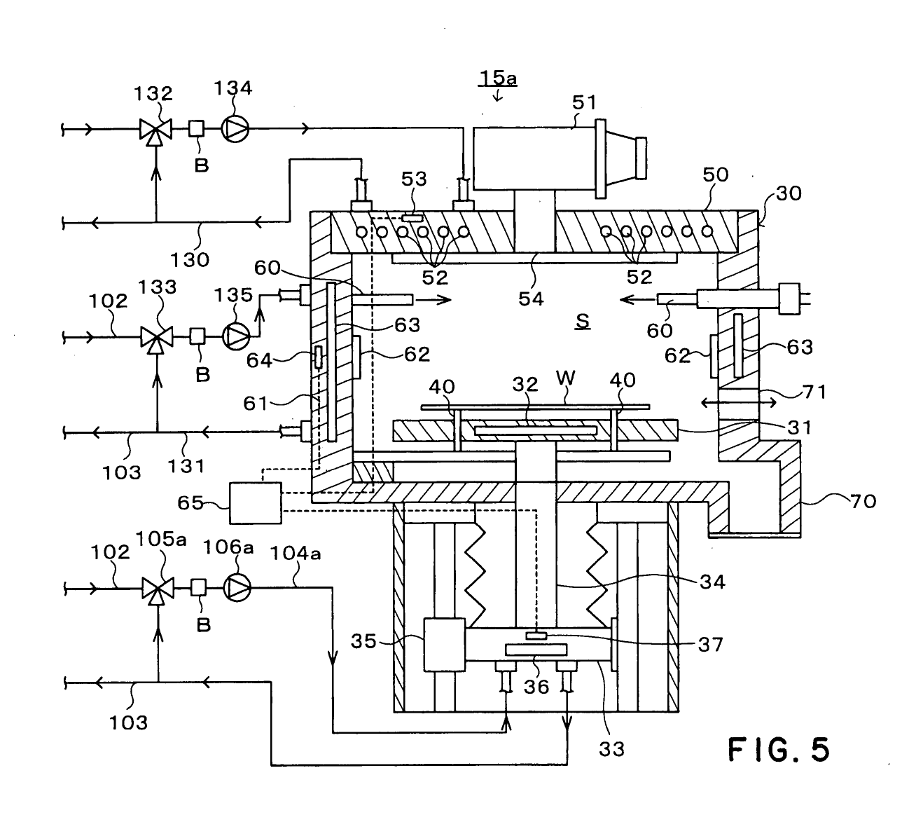

FIG. 6 is an explanatory view showing another use of a three-way valve.

FIG. 7 is a diagrammatic view schematically showing the structure of a temperature controller using cyclic lines and two-way valves.

FIG. 8 is an explanatory plane view showing the mechanism of temperature control of a CVD processing unit.

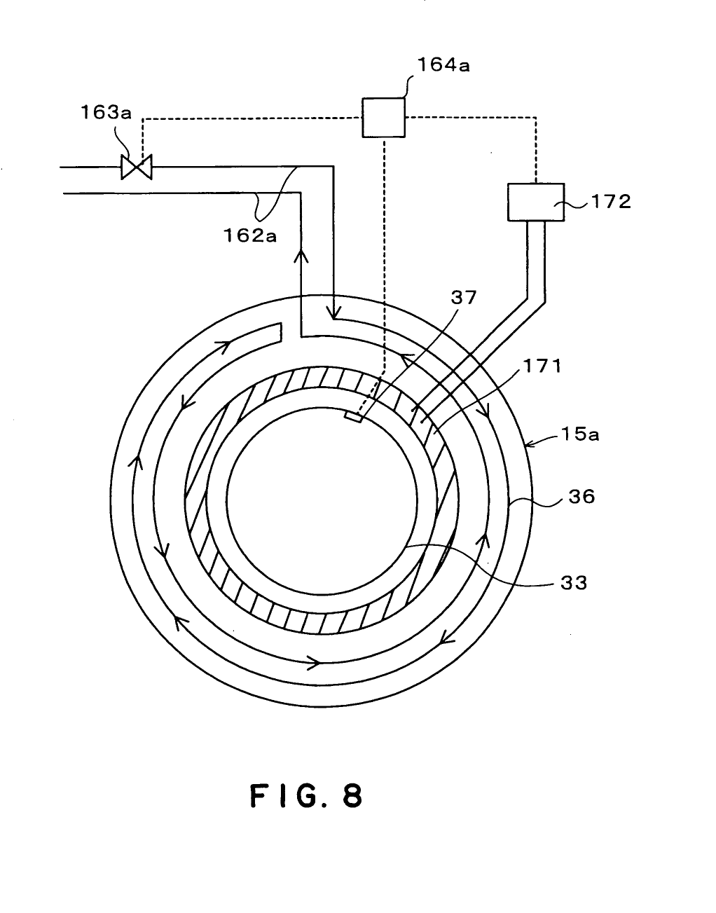

### BEST MODE FOR CARRYING OUT THE INVENTION

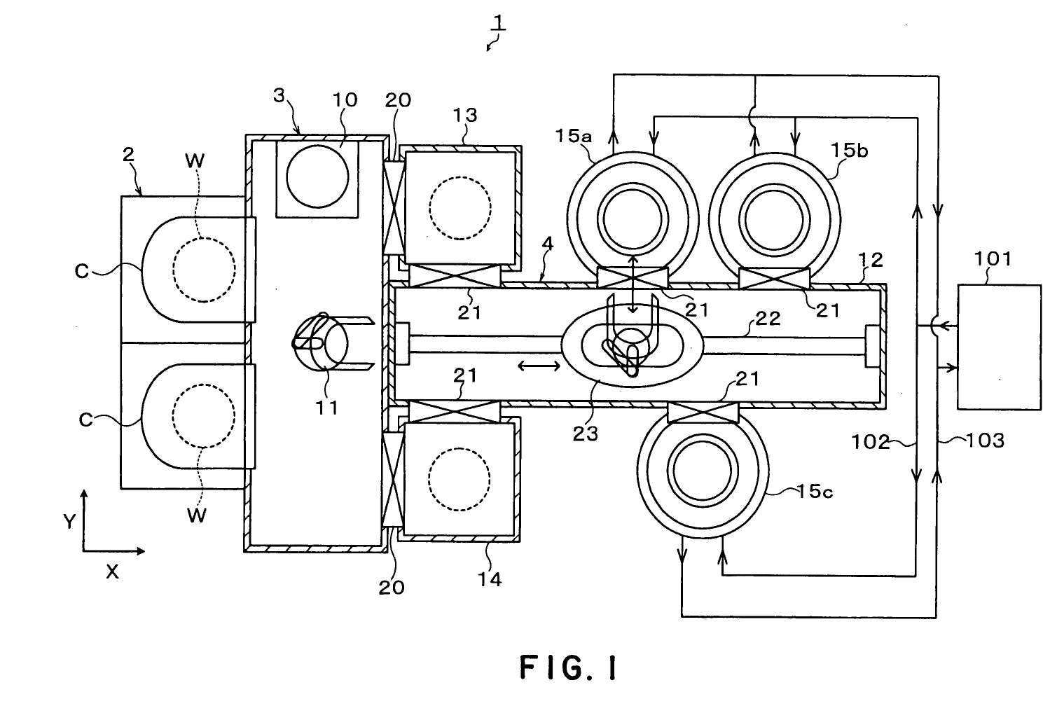

A preferred embodiment of the present invention will be described hereinafter. FIG. 1 is a plane view schematically showing the structure of a substrate processing system 1 in which a temperature controller according to this embodiment is used.

For example, the substrate processing system 1 is composed of a cassette-holding table 2, a carrier vessel 3, and a vacuum processing unit 4 that are connected linearly in the X direction (the horizontal direction in FIG. 1). On the cassette-holding table 2 can be placed an airtight cassette C such as an FOUP (Front Opening Unified Pod) in which a pile of twenty-five wafers W, for example, is contained. On the cassette-holding table 2, two cassettes C, for example, can be placed side by side in the Y direction (the vertical direction in FIG. 1).

The carrier vessel 3 is provided with an alignment stage 10 for positioning a wafer W taken out of the cassette C, and a wafer carrier 11 for carrying the wafer W, having a multiple joint arm. The wafer carrier 11 can access to the cassette C on the cassette-holding table 2, to the alignment stage 10, and to the vacuum processing unit 4, and can thus carry the wafer W. In the vacuum processing unit 4, there is a transfer passage 12 extending in the X direction from the carrier vessel 3. To the transfer passage 12, two load-lock chambers 13, 14 and three CVD (Chemical Vapor Deposition) processing units 15a, 15b, 15c serving as substrate processing units, for example, are connected. The load-lock chamber 13 is connected to each side of the transfer passage 12 on the carrier vessel 3 side, for example. The CVD processing units 15a-15c are connected to both sides of the carrier passage 12 on the positive-direction side of the X direction (the right-hand side in FIG. 1). At the joint of each load-lock chamber 13, 14 and the carrier vessel 3, there is provided a gate valve 20 that is opened when the wafer W is carried. A gate valve 21 is also provided at the joint of the transfer passage 12 and each load-lock chamber 13, 14 and at the joint of the transfer passage 12 and each CVD processing unit 15a, 15b, 15c.

A wafer transfer mechanism 23 movable in the X direction along a rail 22 is provided in the transfer passage 12 in the vacuum processing unit 4. The wafer transfer mechanism 23 has a multiple joint arm for holding the wafer W and can access to the load-lock chambers 13, 14 and to the CVD processing chambers 15a-15c, so that it can transfer the wafer W.

In the substrate processing system 1 having the above-described structure, a wafer W contained in the cassette C on the cassette-holding table 2 is taken out by the wafer carrier 11 and transferred to the alignment stage 10 for positioning. Thereafter, the wafer W is carried in the load-lock chamber 13 by the wafer carrier 11 and then carried in the CVD processing unit 15a, 15b, 15c by the wafer transfer mechanism 23 from the load-lock chamber 13 for CVD processing. The wafer W that has been subjected to CVD processing is carried into the load-lock chamber 13 by the wafer transfer mechanism 23 and is then returned to the cassette C by the wafer carrier 11.

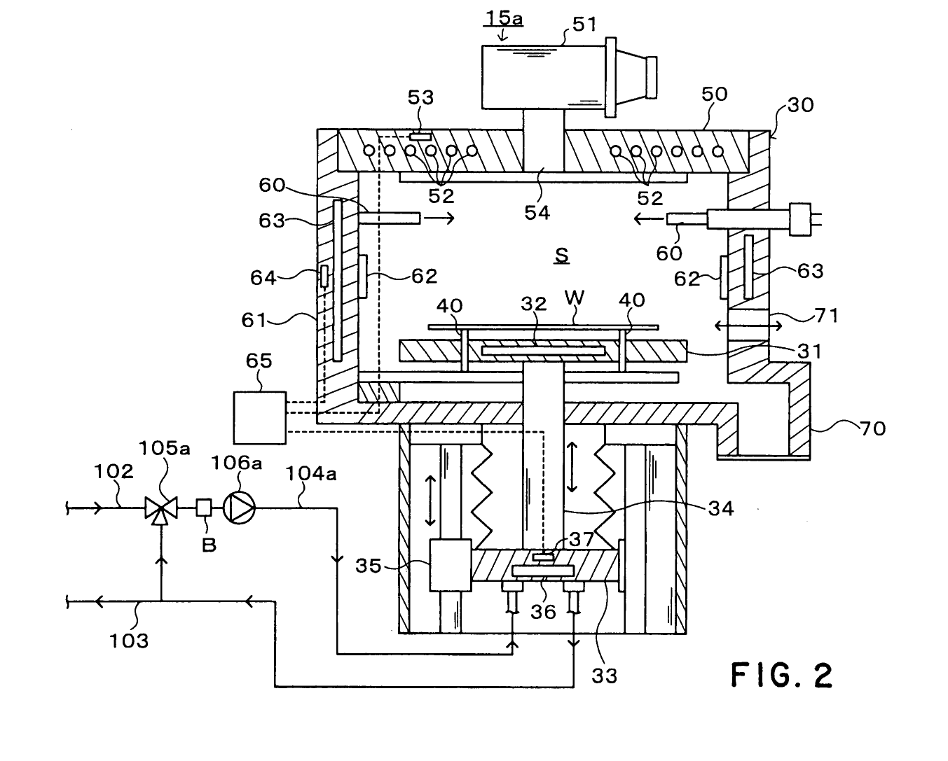

The structure of the CVD processing units 15a-15c whose temperatures are controlled by the temperature controller according to this embodiment will now be described. FIG. 2 is a longitudinal sectional view schematically showing the structure of the CVD processing unit 15a.

For example, the CVD processing unit 15a has, as a processing vessel, a nearly cylindrical frame 30 that forms a processing chamber S. In the frame 30, there is a table 31 for holding a wafer W. The table 31 has a first built-in heater 32 for raising the temperature of the wafer W placed on it. A rod 34 extending in the longitudinal direction, erecting on a rod stage 33, supports the table 31. The rod stage 33 is interlocked with an elevating mechanism 35 provided under the frame 30. With this elevating mechanism 35, the rod stage 33 goes up and down, and the table 31 can thus go up and down in the frame 30. In the above-described rod stage 33 that conducts the heat of the table 31, there are a first cooling-medium-flowing part 36 in which a cooling medium supplied by a refrigerator 101, which will be described later, flows, and a first temperature sensor 37 for sensing the temperature of the rod stage 33.

Inside the frame 30, there are support pins 40 that support a wafer W when the wafer W is carried in or out of the frame 30. After the support pins 40 have supported the wafer W, the table 31 is elevated, so that the wafer W can be delivered to the table 31.

A microwave generator 51 is provided on the ceiling 50 of the frame 30. The ceiling 50 has a second cooling-medium-flowing part 52 in which a cooling medium supplied by the refrigerator 101, which will be described later, flows, and a second temperature sensor 53 for sensing the temperature of the ceiling 50. The second cooling-medium-flowing part 52 is a channel whose plane form is a coil whose center is the microwave generator 54 positioned in the center of the ceiling 50, for example.

The frame 30 has a gas inlet pipe 60 through which a gas to be used for plasma production is introduced into the chamber S. Further, on the inner surface of the sidewall 61 of the frame 30, a second heater 62 for raising the internal temperature of the chamber S is provided. In the sidewall 61 of the frame 30 are provided a third cooling-medium-flowing part 63 in which a cooling medium supplied by the refrigerator 101, which will be described later, flows, and a third temperature sensor 64 for sensing the temperature of the sidewall 61. The third cooling-medium-flowing part 63 is a meandering channel that makes a loop in the annular sidewall 61, for example.

For example, the results of sensing carried out by the above-described temperature sensors 37, 53, 64 can be output on a controller 65 that controls the operation of various component parts of the CVD processing unit 15a.

At its lower part, the frame 30 has an exhaust vent 70 through which the atmosphere in the processing chamber S is exhausted. The sidewall 61 of the frame 30 has an opening 71 through which a wafer W is carried in or out.

In this embodiment, the structure of the CVD processing unit 15b and that of the CVD processing unit 15c are quite the same as that of the CVD processing unit 15a, so that they will not be described any more.

In the CVD processing units 15a-15c having the above-described structure, a wafer W is carried in the processing chamber S with the internal temperature of the processing chamber S and the temperature of the table 31 raised to predetermined ones by the first heater 32 and the second heater 62, respectively. The wafer W carried in the processing chamber S is supported by the support pins 40 and is then placed on the table 31. Thereafter, a predetermined gas is introduced into the processing chamber S through the gas inlet pipe 60, and to this gas, microwaves generated by the microwave generator 51 are applied. By the application of the microwaves, plasma is produced in the processing chamber S, and with this plasma, a predetermined film is formed on the wafer W.

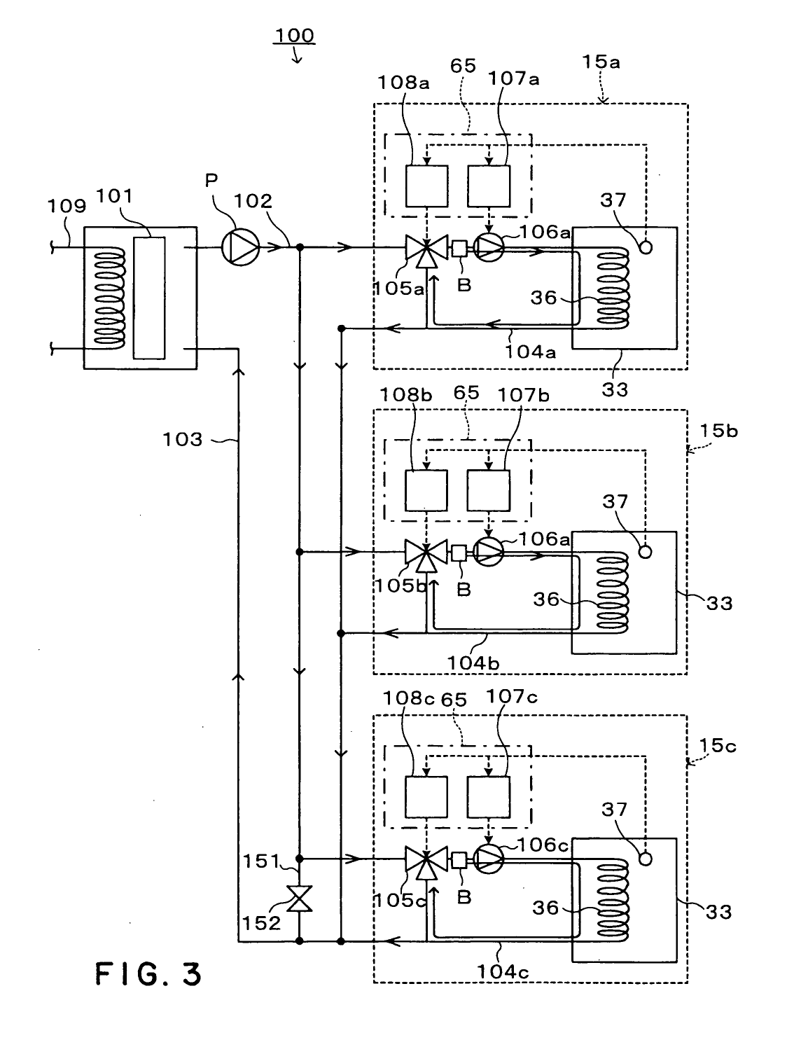

Next, a temperature controller 100 for controlling the temperatures of the above-described CVD processing units 15a-15c will be described. FIG. 3 is a diagrammatic view schematically showing the structure of the temperature controller 100.

The temperature controller 100 has one refrigerator 101, a supply line 102 for supplying a cooling medium to the CVD processing units 15a-15c from the refrigerator 101, and a feedback line 103 for feeding the cooling medium back to the refrigerator 101 from the CVD processing units 15a-15c. Further, the temperature controller 100 has circuits 104a, 104b, 104c provided in the CVD processing units 15a, 15b, 15c, respectively, each connected to the supply line 102 and to the feedback line 103.

A pump P for feeding the cooling medium with pressure to the CVD processing units 15a-15c is provided on the upper stream side of the supply line 102. The supply line 102 diverges and is connected to the circuits 104a-104c in the CVD processing units 15a-15c. For example, three-way valves 105a, 105b, 105c, regulating valves, are provided at the joints of the supply line 102 and the circuits 104a, 104b, 104c, respectively. These three-way valves 105a-105c can switch states from one in which the cooling medium circulates between the refrigerator 101 and the CVD processing units 15a-15c through the supply line 102, the circuits 104a-104c, and the feedback line 103, to the other in which the cooling medium circulates substantially only around the circuits 104a-104c, or from the latter state to the former. Further, with the three-way valves 105a-105c, it is possible to regulate the flow rates of the cooling medium that flows, from the supply line 102, into the circuits 104a-104c around which the cooling medium is circulating.

The circuits 104a-104c are laid out in predetermined objects of temperature control in the CVD processing units 15a-15c, such as the rod stages 33, as shown in FIGS. 2 and 3. Namely, the first cooling-medium-flowing parts 36 in the CVD processing units 15a-15c constitute a part of the circuits 104a-104c. The circuits 104a, 104b, 104c have circulating pumps 106a, 106b, 106c for facilitating circulation of the cooling medium around the circuits 104a-104c, respectively.

Buffer tanks B for the cooling medium are provided between the three-way valves 105a-105c and the corresponding circulating pumps 106a-106c. Each buffer tank B has an air escape hole, a relief valve, etc. Therefore, if pressure changes occur in the circuits 104a-104c due to operation of the circulating pumps 106a, 106b, 106c, the buffer tanks B suppress these changes and can thus ensure the steady flow of the cooling medium.

The feedback line 103 is connected to the circuits 104a-104c, as shown in FIG. 3, so that the cooling medium that has passed through the circuits 104a-104c can be fed back to the refrigerator 101. A by-pass pipe 151 bypassing the CVD processing units 15a-15c is laid so that it links the supply line 102 with the feedback line 103. The by-pass pipe 151 has an on-off valve 152. With this valve, it is possible to prevent abnormal increase of the pressure in the supply line 102 that can occur when the circuits 104a-104c are closed, for example, by the three-way valves 105a-105c or the like. Thus, the on-off valve 152 functions as a kind of relief valve. On/OFF control of the on-off valve 152 may be interlocked with the three-way valves 105a-105c. Namely, for example, the on-off valve 152 may be controlled so that it opens when all the three-way valves 105a-105c operate to shut the supply line 102.

The controllers 65 in the above-described CVD processing units 15a-15c have pump operation controllers 107a, 107b, 107c for controlling the operation of the circulating pumps 106a-106c according to the temperatures sensed by the first temperature sensors 37 in the CVD processing units 15a-15c. With the pump operation controllers 107a-107c, the operation of the circulating pumps 106a-106c can be controlled according to the temperatures of the rod stages 33, thereby regulating the flow velocity of the cooling medium in the circuits 104a-104c. Further, the controllers 65 have valve controllers 108a, 108b, 108c for controlling the operation of the three-way valves 105a-105c according to the temperatures sensed by the first temperature sensors 37. With these valve controllers, the opening of the three-way valves 105a-105c can be controlled according to the temperatures of the rod stages 33, thereby allowing or not allowing the cooling medium to flow into the circuits 104a-104c from the supply line 102, or regulating the flow rates of the cooling medium flowing into the circuits. The refrigerator 101 has a line 109 in which industrial circulating water (city water) or the like flows.

Next, the operation of the temperature controller 100 having the above-described structure will be described. When the refrigerator 101 starts operation and the cooling medium is fed to the supply line 102 with the pump P, the cooling medium is, via the supply line 102, distributively fed to the circuits 104a-104c in the CVD processing units 15a-15c and is then fed back to the refrigerator 101 from the circuits 104a-104c via the feedback line 103. Further, for example, if the flow of the cooling medium from the supply line 102 to the circuits 104a-104c is cut off by the three-way valves 105a-105c in the CVD processing units 15a-15c, the cooling medium circulates around the circuits 104a-104c with the circulating pumps 106a-106c operation.

Furthermore, when both the flow of the cooling medium from the supply line 102 to the circuits 104a-104c and the flow of the cooling medium in the circuits 104a-104c are maintained by regulating the degree of openness of the three-way valves 105a-105c, a predetermined amount of the cooling medium supplied by the refrigerator 101 is taken in the cooling medium circulating around the circuits 104a-104c. The cooling medium in the same amount as that of the cooling medium flown into the circuits 104a-104c from the supply line 102 flows out of the circuits 104a-104c into the feedback line 103 and is fed back to the refrigerator 101 through the feedback line 103.

Although a three-way valve is usually used to distribute a fluid flowing into the valve body from one channel to two other channels, the above-described three-way valves 105a-105c shown in FIG. 3 use this mechanism conversely. The three-way valves 105a-105c allow a fluid flowing into them from the supply line 102 and a fluid flowing into them from the exits of the circuits 104a-104c to flow toward the inlets of the circuits 104a-104c. Namely, they control the mixing ratio of fluids flowing into them from two channels and let the fluid mixture to flow toward the inlets of the circuits 104a-104c. The mixing ratio can be controlled to change from 0% to 100% arbitrarily.

For example, during CVD processing conducted in the CVD processing units 15a-15c, the temperatures of the rod stages 33 are controlled so that they do not exceed predetermined temperatures, in order to stabilize the temperatures of the tables 31. During CVD processing, the first temperature sensors 37 continually monitor the temperatures of the rod stages 33 in the CVD processing units 15a-15c.

For example, in the case where the temperature of the cooling medium supplied by the refrigerator 101 is −30° C. and the upper limit of the temperature of the rod stage 33 in the CVD processing unit 15a is set to −20° C., if the temperature of the rod stage 33 is as low as below −20° C., the flow of the cooling medium from the supply line 102 to the circuit 104a is cut off by the three-way valve 105a, and the circulation of the cooling medium around the circuit 104a at a predetermined velocity is caused by the circulating pump 106a. At this time, the cycle of circulation of the cooling medium around the circuit 104a is relatively short, so that the cooling medium in the circuit 104a can remain nearly uniform in temperature. Therefore, the difference between the temperature of the cooling medium at the inlet of the first cooling-medium-flowing part 36 and that at the outlet of the same is also small, so that the temperature of the rod stage 33 is uniformly maintained. Moreover, at this time, supply of the cooling medium by the refrigerator 101 is suspended and temperature control is done by the cooling medium in the circuit 104a, whose amount is small, so that it is possible to economize electric power to be consumed by the refrigerator, etc.

For example, when the temperature of the rod stage 33 exceeds −20° C., the degree of openness of the three-way valve 105a is regulated so that the cooling medium at a low temperature of −30° C. is taken into the circuit 104a from the supply line 102, with the circulation of the cooling medium around the circuit 104a maintained. Thus, the temperature of the cooling medium circulating around the circuit 104a decreases and the temperature of the rod stage 33 lowers.

Also in the CVD processing units 15b, 15c, the temperatures of the rod stages 33 can be kept below temperatures separately predetermined for the CVD processing units 15b, 15c, by switching states from one in which the cooling medium is circulating around the circuits 105b, 105c to the other in which the cooling medium is freshly taken in the circuits 105b, 105c from the supply line 102, or from the latter state to the former, depending on the temperatures of the rod stages 33 sensed by the first temperature sensors 37.

According to the above-described embodiment, since the supply line 102 that links one refrigerator 101 with a plurality of the CVD processing units 15a-15c is laid so that the cooling medium can be distributively fed to the CVD processing units 15a-15c from the refrigerator 101, the total number of the pipes required is smaller than that in the prior art, which can bring about reduction in piping space and cost. Moreover, a smaller space is enough for installing the refrigerator 101. Since the cooling medium is circulated around the short-length circuits 104a-104c laid out in the CVD processing units 15a-15c so that the cooling medium in the circuits 104a-104c can remain uniform in temperature, the temperatures of the rod stages 33 in the CVD processing units 15a-15c can be controlled uniformly and stably.

Since the three-way valves 105a-105c are provided at the joints of the supply line 102 and the circuits 104a-104c, the cooling medium in the supply line 102 can be freshly taken in the circuits 104a-104c, as needed. Therefore, if the temperatures of the rod stages 33 become high, the cooling medium at a low temperature supplied by the refrigerator 101 is mixed with the cooling medium circulating around the circuits 104a-104c to decrease the temperature of the cooling medium in the circuits 104a-104c. It is therefore possible to lower the temperatures of the rod stages 33 rapidly. Moreover, depending on the temperatures sensed by the first temperature sensors 37, the three-way valves 105a-105c are controlled, so that temperature control can be done accurately and rapidly.

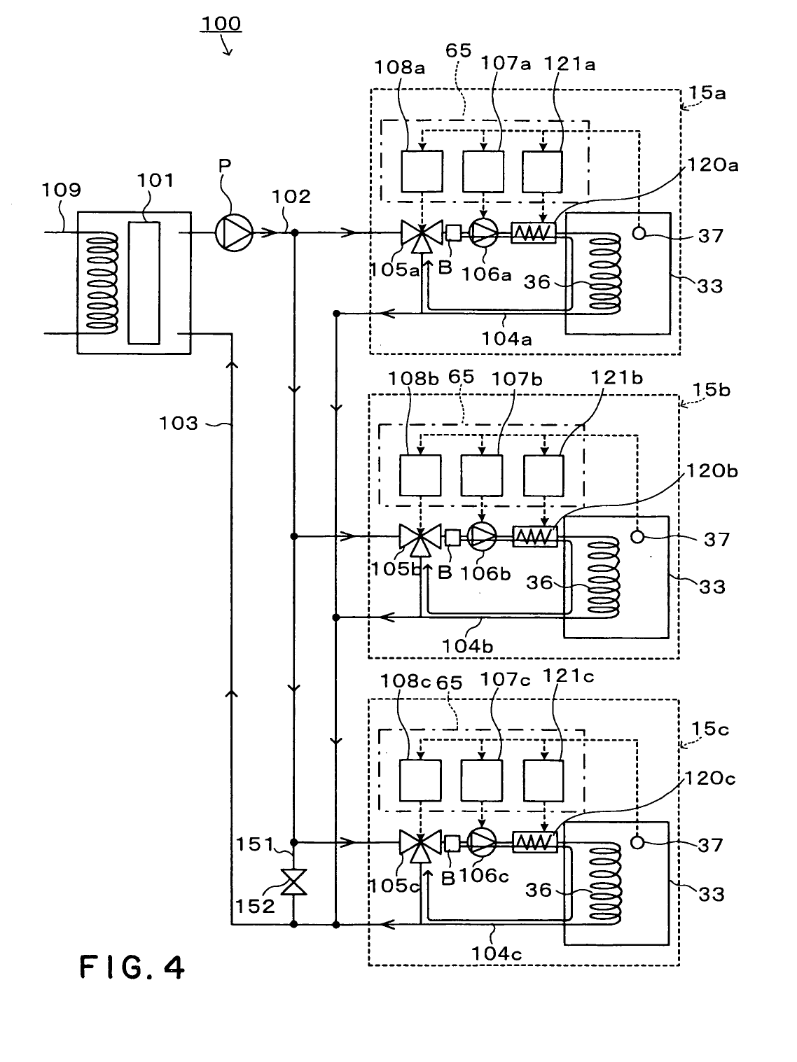

The circuits 104a-104c in the CVD processing units 15a-15c in the aforementioned embodiment may be provided with heaters 120a, 120b, 120c, as shown in FIG. 4. In this case, the controllers 65 are provided with heat controllers 121a, 121b, 121c for controlling heating with the heaters 120a-120c according to the temperatures sensed by the first temperature sensors 37. In such a case, if the temperatures of, for example, the rod stages 33 in the CVD processing units 15a-15c become lower than the target temperatures, the heat controllers 121a-121c operate the heaters 120a-120c to raise the temperature of the cooling medium in the circuits 104a-104c. By this, the temperatures of the rod stages 33 can be positively raised, and they can be regulated to the desired target temperatures, for example.

Although the temperatures of the rod stages 33 are controlled in the above embodiment in order to stabilize the temperatures of the tables 31, the temperatures of the tables 31 may be controlled directly by laying out the circuits 104a-104c in the tables 31.

Further, although the rod stages 33 in the CVD processing units 15a-15c are the objects of temperature control in the above embodiment, other parts of the CVD processing units 15a-15c, such as the ceiling 50 and sidewall 61 of the frame 30, may be the objects of temperature control. In this case, in each CVD processing unit 15a, 15b, 15c, a circuit 130 is laid out in the second cooling-medium-flowing part 52, and a circuit 131, in the third cooling-medium-flowing part 63, and each circuit is connected to the supply line 102 and to the feedback line 103. The circuits 130, 131 have three-way valves 132, 133 and circulating pumps 134, 135, respectively. The three-way valves 132, 133 and the operation of the circulating pumps 134, 135 are controlled according to the temperatures sensed by the second temperature sensor 53 and the third temperature sensor 64, respectively, like in the above-described temperature control of the rod stages 33, thereby controlling the temperatures of the ceiling 50 and sidewall 61 of each CVD processing unit.

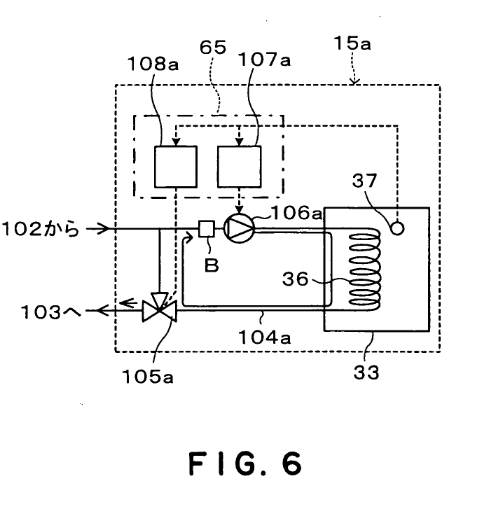

Although the three-way valve in the aforementioned embodiment is used to control the mixing ratio of fluids flowing into the valve from two channels and allow the fluid mixture to flow in another channel, which is converse to the conventional use of a three-way valve, it may, of course, be used in the conventional manner that a fluid flowing into the valve from one channel is distributed to two other channels. FIG. 6 is a view showing this use of the three-way valve in the CVD processing unit 15a shown in FIG. 3. In this case, the three-way valve 105a is used at the junction of three lines at which the fluid from the circuit 104a is distributed to the feedback line 103 and the supply line 102. Even when the three-way valve is used in this manner, there can, of course, be obtained the same actions and effects as those described above.

In the above-described embodiment, a circuit is laid out in each CVD processing unit, and the temperature of an object of temperature control in the CVD processing unit is controlled by distributing a fluid or regulating the flow rate of the fluid by the three-way valve. However, simpler piping can be employed, and a conventional two-way valve can be used instead of the three-way valve.

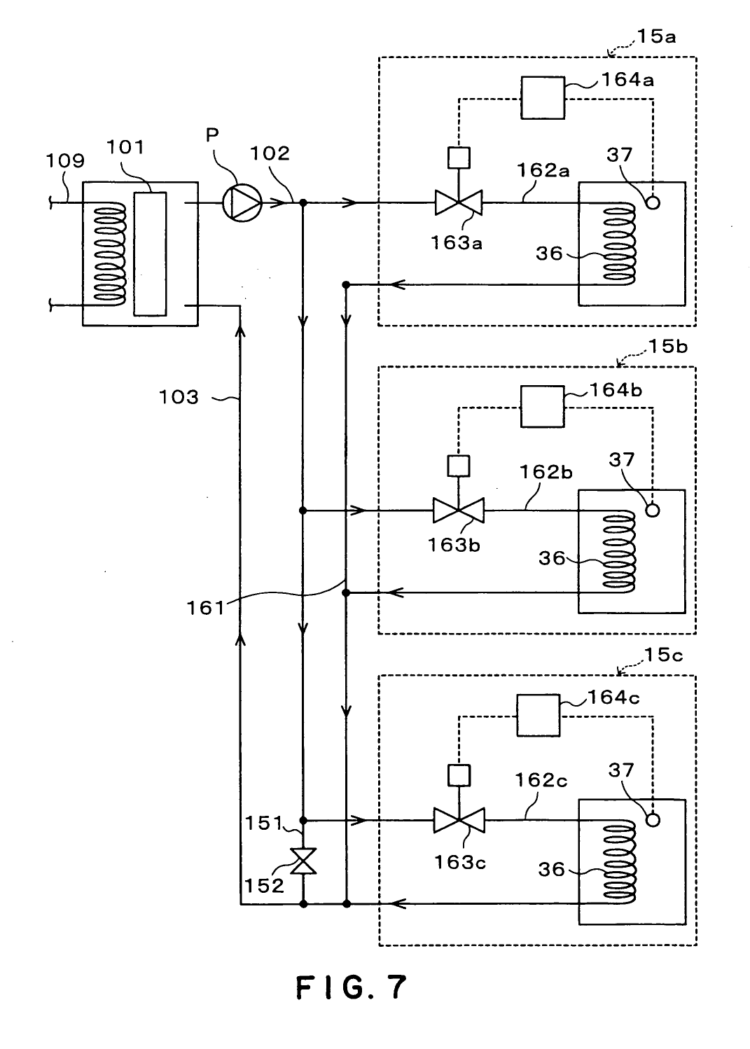

FIG. 7 shows an embodiment using a two-way valve. In this embodiment, a cyclic line 162a is laid in a CVD processing unit 15a, so that a cooling medium taken in from a supply line 102 passes through a cooling-medium-flowing part 36 and flows into a feedback line 161 that is connected to a feedback line 103. This cyclic line 162a has a valve 163a, and by controlling ON/OFF of this valve 163a, it is possible to regulate the flow rate of the cooling medium flowing into the cooling-medium-flowing part 36. ON/OFF of the valve 163a is controlled with a controller 164a according to the signal sent by a temperature sensor 37. Cyclic lines 162b, 162c, valves 163b, 163c, and controllers 164b, 164c in the other CVD processing units 15b, 15c are quite the same in structure as those in the CVD processing unit 15a.

Further, in the CVD processing unit 15a, the temperature of an object of temperature control, such as the temperature of a rod stage 33, is controlled by cooling with a cooling medium, such as a chiller or water, flowing in the above-described cooling-medium-flowing part 36, and also by heating with a heater 171. Temperature control of the heater 171 itself is conducted by controlling a power source 172.

Therefore, in this case, if the object of temperature control reaches a high temperature in excess of a predetermined upper limit temperature, e.g., a temperature of more than −10° C., the valve 163a is opened in response to the signal sent from the temperature sensor 37 to allow the cooling medium to flow into the cooling-medium-flowing part 36 from the circuit 162a. As for the heater 171, if the temperature of the object of temperature control becomes below a predetermined temperature, e.g., a temperature of less than −20° C., the power source 172 is controlled to operate the heater 171 for heating. This control is also done with the controller 164a. The other CVD processing units 15b, 15c have quite the same structure as the CVD processing unit 15a.

Such temperature control using the cyclic lines 162a-162c and the valves 163a-163c is effective to the case where an object of temperature control requires relatively rough temperature control, and is advantageous in that it requires only simpler piping as compared with the above-described temperature control using the feedback line and the three-way valves in combination and that it requires no circulating pump, etc.

One embodiment of the present invention has been described. The present invention is not limited to this embodiment, and many other embodiments are possible. For example, although the temperature controller 100 controls the temperatures of three CVD processing units in this embodiment, the number of CVD processing units to be subjected to temperature control may be freely selected. The substrate processing units to be subjected to temperature control are not limited to the CVD processing units 15a-15c and they may be other substrate processing units that require temperature control, such as non-CVD film-deposition processing units, etching processing units, and heat processing units. Further, the substrate processing units to be subjected to temperature control are not limited to ones installed in one substrate processing system 1, and they may be ones installed in two or more substrate processing systems. Although the substrate described in this embodiment is a wafer W, it may be other substrate such as a FPD (flat panel display) substrate, a mask substrate, or a reticle substrate.

1. A temperature controlling method for a substrate processing system comprising a plurality of substrate processing units each having objects of temperature control, characterized in that
the temperatures of the objects of temperature control in the substrate processing units are controlled by distributively feeding a cooling medium to the substrate processing units from one refrigerator.

2. The method according to claim 1, wherein in each substrate processing unit, the cooling medium supplied by the refrigerator is circulated around a circuit that is laid out in the object of temperature control.

3. The method according to claim 2, wherein the temperatures of the objects of temperature control are separately controlled by separately regulating the flow velocity of the cooling medium in the circuits in the substrate processing units.

4. The method according to claim 2, wherein the following operation (a) or (b) is selectively conducted depending on the temperatures of the objects of temperature control:
(a) suspending supply of the cooling medium from the refrigerator to the circuits in the substrate processing units, and continuing to control the temperatures of the objects of temperature control substantially only by the cooling medium circulating around the circuits; or
(b) controlling the temperatures of the objects of temperature control by circulating the cooling medium around the circuits, while supplying the cooling medium from the refrigerator to the circuits in the substrate processing units.

5. The method according to claim 4, wherein the temperatures of the objects of temperature control are separately controlled by separately regulating the flow velocity of the cooling medium in the circuits in the substrate processing units.

6. A substrate processing system comprising:
a plurality of substrate processing units having objects of temperature control,
a refrigerator,
a supply line for supplying a cooling medium from the refrigerator to the substrate processing units,
a feedback line for feeding the cooling medium back to the refrigerator from the substrate processing units,
circuits, each connected to the supply line and to the feedback line, which allow the cooling medium to circulate through the objects of temperature control in the substrate processing units, and
regulating valves for regulating separately the flow rates of the cooling medium flowing into the circuits from the supply line.

7. The system according to claim 6, wherein the regulating valves are three-way valves that can switch states from
one in which the cooling medium circulates substantially only around the circuits, to
the other in which the cooling medium circulates between the refrigerator and the substrate processing units through the supply line, the circuits, and the feedback line,
or from the latter state to the former.

8. The system according to claim 6, further comprising:
temperature sensors for sensing the temperatures of the objects of temperature control, and
valve controllers for controlling the regulating valves according to the temperatures sensed by the temperature sensors.

9. The system according to claim 8, further comprising:
heaters for heating the cooling medium circulating around the circuits, and
heat controllers for controlling the heaters according to the temperatures sensed by the temperature sensors.

10. The system according to claim 6, wherein the circuits are provided with pumps to circulate the cooling medium.

11. The system according to claim 10, wherein the circuits are provided with buffer tanks for the cooling medium.

12. The system according to claim 6, further comprising:
a by-pass line that by-passes the substrate processing units and links the supply line with the feedback line, and
an on-off valve for opening or closing the by-pass line.

13. The system according to claim 6, wherein the substrate processing units are useful to process substrates with plasma produced in them.
